(19) United States
(12) Patent Application Publication
(10) Pub. No.: US 2023/0326908 A1
(43) Pub. Date: Oct. 12, 2023

(54) DISPLAY DEVICE

(71) Applicant: KYOCERA Corporation, Kyoto-shi, Kyoto (JP)

(72) Inventor: Masaya TAMAKI, Yokohama-shi, Kanagawa (JP)

(21) Appl. No.: 18/021,362

(22) PCT Filed: Aug. 2, 2021
(86) PCT No.: PCT/JP2021/028587

§ 371 Date: Feb. 14, 2023

(30) Foreign Application Priority Data
Aug. 18, 2020 (JP) 2020-138151

(51) Int. Cl. H01L 33/62; H01L 25/075; H01L 27/15

(52) U.S. Cl. CPC H01L 25/0753; H01L 27/156; H01L 33/62

(57) ABSTRACT

A display device includes a cavity structure and a plurality of pixel units. The cavity structure includes a display surface and a plurality of cavities in the display surface. Each pixel unit of the plurality of pixel units includes a first light emitter and a second light emitter located in a corresponding cavity of the plurality of cavities. The first light emitter and the second light emitter are arranged in a same pattern in each cavity of the plurality of cavities. The each pixel unit of the plurality of pixel units includes a redundant structure configured to cause one of the first light emitter and the second light emitter to be driven to emit light. The first light emitter and the second light emitter are different in that they are driven according to the each pixel unit.

### TECHNICAL FIELD

The present disclosure relates to a display device including self-luminous light emitters such as light-emitting diodes (LEDs).

### BACKGROUND OF INVENTION

Known display devices are described in, for example, Patent Literatures 1 and 2.

### CITATION LIST

### Patent Literature

Patent Literature 1: Japanese Unexamined Patent Application Publication No. 2009-151220
Patent Literature 2: Japanese Unexamined Patent Application Publication (Translation of PCT Application) No. 2016-512347

### SUMMARY

In an aspect (first aspect) of the present disclosure, a display device includes a cavity structure and a plurality of pixel units. The cavity structure includes a display surface and a plurality of cavities in the display surface. Each pixel unit of the plurality of pixel units includes a first light emitter and a second light emitter located in a corresponding cavity of the plurality of cavities. The first light emitter and the second light emitter are arranged in a same pattern in each cavity of the plurality of cavities. The each pixel unit of the plurality of pixel units includes a redundant structure configured to cause one of the first light emitter and the second light emitter to be driven to emit light. The first light emitter and the second light emitter are different in that they are driven according to the each pixel unit.

In an aspect (second aspect) of the present disclosure, a display device includes a cavity structure and a plurality of pixel units. The cavity structure includes a display surface and a plurality of cavities in the display surface. Each pixel unit of the plurality of pixel units includes a first light emitter and a second light emitter located in a corresponding cavity of the plurality of cavities. The first light emitter and the second light emitter are arranged in a same pattern in each cavity of the plurality of cavities. The each pixel unit of the plurality of pixel units includes a redundant structure configured to cause one of the first light emitter and the second light emitter to be driven to emit light. Each of the first light emitter and the second light emitter includes a first terminal and a second terminal spaced from each other as viewed in a plan view, and includes an emission portion located adjacent to the first terminal or to the second terminal in a corresponding one of the first light emitter and the second light emitter. Each of the plurality of cavities includes, on a bottom surface of the cavity, a first electrode connected to the first terminal and a second electrode connected to the second terminal. The first electrode or the second electrode corresponding to the first terminal or the second terminal located adjacent to the emission portion is in a central portion of the bottom surface.

### BRIEF DESCRIPTION OF THE DRAWINGS

The objects, features, and advantages of the present disclosure will become more apparent from the following detailed description and the drawings.

FIG. 1 is a schematic partial plan view of a display device according to an embodiment of the present disclosure.

FIG. 2 is a cross-sectional view taken along line A1-A2 in FIG. 1.

FIG. 3 is a schematic cross-sectional view of the display device according to the embodiment of the present disclosure.

FIG. 4 is a plan view of multiple pixel units included in the display device according to the embodiment of the present disclosure, illustrating drive control over the pixel units.

FIG. 5 is a plan view of multiple pixel units included in the display device according to the embodiment of the present disclosure, illustrating drive control over the pixel units.

FIG. 6 is a plan view of multiple pixel units included in the display device according to the embodiment of the present disclosure, illustrating drive control over the pixel units.

FIG. 7 is a schematic partial plan view of a display device according to a variation of the embodiment of the present disclosure.

FIG. 8 is a schematic partial plan view of a display device according to another embodiment of the present disclosure.

FIG. 9 is a cross-sectional view taken along line A3-A4 in FIG. 8.

FIG. 10 is a block diagram of the display device according to the embodiment of the present disclosure.

### DESCRIPTION OF EMBODIMENTS

The structure that forms the basis of a display device according to one or more embodiments of the present disclosure will be described. The display device described in Patent Literature 1 includes a substrate on which pixel units are arranged. The pixel units include self-luminous light emitters such as light-emitting diodes (LEDs). When light emitters are mounted on the display device, for example, one or more light emitters can be defective due to faulty connection to electrodes on the substrate or other causes. Pixel units with defective light emitters may be in a non-emission state, lowering the manufacturing yield.

To avoid lowering the manufacturing yield due to defective light emitters, the display device described in Patent Literature 2 includes pixel units including a redundant array of light emitters (hereafter also referred to as redundant light emitters) in addition to regular light emitters. For a pixel unit with a defective regular light emitter, the redundant light emitter is driven to prevent the pixel unit from being in a non-emission state.

In the display device described in Patent Literature 2, light emitted from each pixel unit may have a different intensity distribution between when the regular light emitter is driven and when the redundant light emitter is driven. This may cause non-uniformity in display images, lowering the image quality.

A display device according to one or more embodiments of the present disclosure will now be described with reference to the accompanying drawings. Each figure referred to below illustrates main components and other elements of the display device according to one or more embodiments. In the embodiments, the display device may include known components that are not illustrated, for example, circuit boards, wiring conductors, control integrated circuits (ICs), and large-scale integration (LSI) circuits.

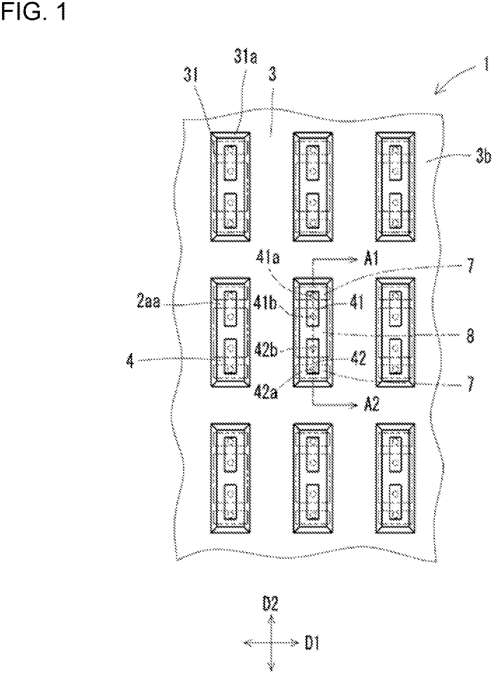

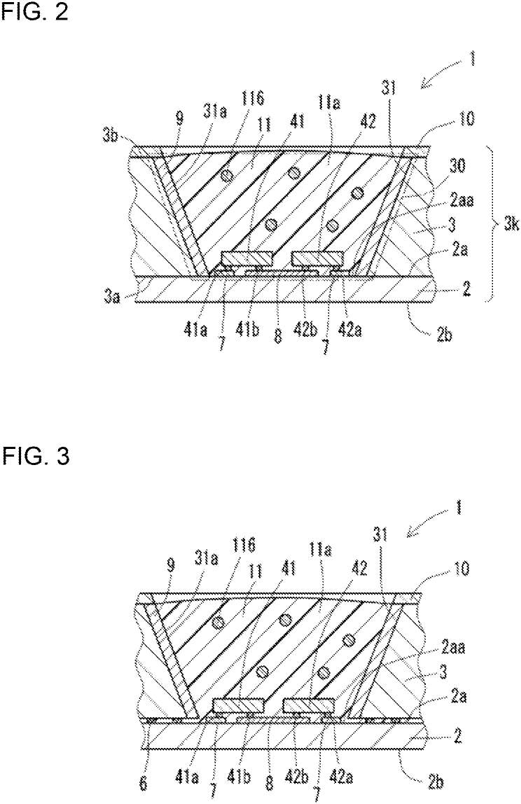

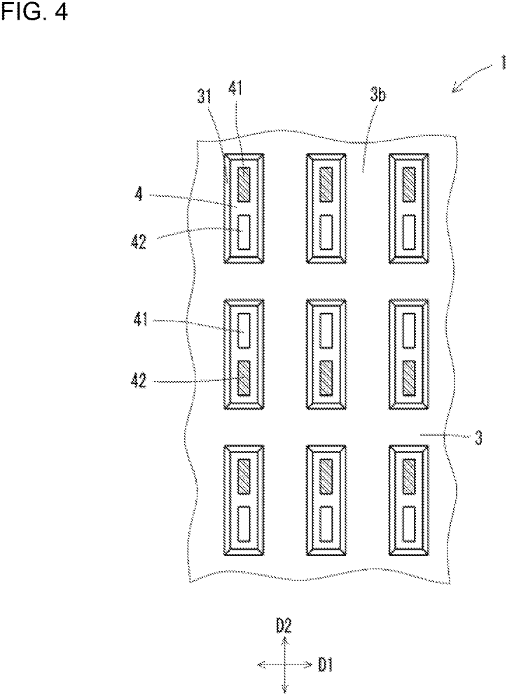

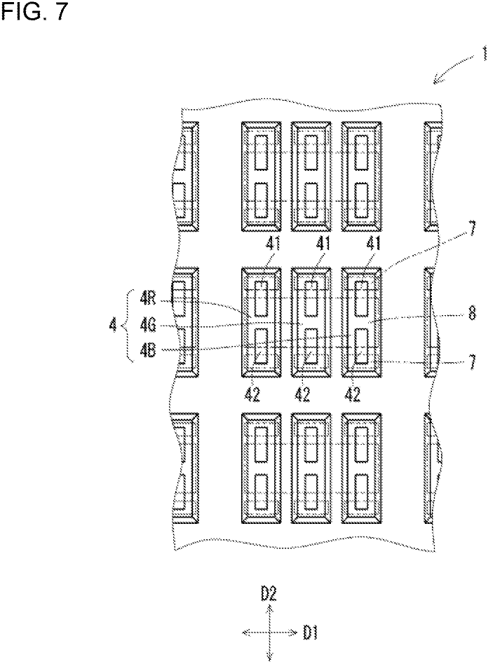

FIG. 1 is a schematic partial plan view of a display device according to an embodiment of the present disclosure. FIG. 2 is a cross-sectional view taken along line A1-A2 in FIG. 1. FIG. 3 is a schematic cross-sectional view of the display device according to the embodiment of the present disclosure. FIGS. 4 to 6 are each a plan view of multiple pixel units included in the display device according to the embodiment of the present disclosure, illustrating drive control over the pixel units. FIG. 7 is a schematic partial plan view of a display device according to a variation of the embodiment of the present disclosure. The cross-sectional view of FIG. 3 corresponds to the cross-sectional view of FIG. 2. The plan views of FIGS. 4 to 6 and 7 each correspond to the plan view of FIG. 1. FIGS. 1 and 7 do not illustrate transparent members, a light reflective film, or a light absorbing film. In FIGS. 4 to 6, the hatched elements indicate either first light emitters or second light emitters that are being driven (in other words, emitting light).

In a first aspect of the disclosure, a display device 1 includes a cavity structure 3k (illustrated in FIG. 2) and multiple pixel units 4. The cavity structure 3k includes a display surface (a third surface 3b of a second substrate 3) and multiple cavities 30 (illustrated in FIG. 2) in the display surface. Each pixel unit 4 includes a first light emitter 41 and a second light emitter 42 located in the corresponding cavity 30. The first light emitter 41 and the second light emitter 42 are arranged in the same pattern in each cavity 30. Each pixel unit 4 includes a redundant structure configured to cause one of the first light emitter 41 and the second light emitter 42 to be driven to emit light. The first light emitter 41 and the second light emitter 42 are different in that they are driven according to the each pixel unit 4.

The above structure produces the advantageous effects described below. Each pixel unit 4 includes the redundant structure including the first light emitter 41 and the second light emitter 42, one of which is redundant. This improves the manufacturing yield. A different one of the first light emitter 41 or the second light emitter 42 is driven for each pixel unit 4. This reduces non-uniformity in display images.

The structure may include one or more cavities 30. The number of cavities 30 may correspond to the number of pixel units 4. In a structure with multiple cavities 30, the cavities 30 may be individually located in separate members or may be collectively located in, for example, a substrate. In the display device 1 in the example below, the cavities 30 are collectively located in a first substrate 2 and in the second substrate 3.

For the cavities 30 being located in multiple members that are combined together, adjacent members may be connected using, for example, an arm- or plate-like connector or an adhesive. For the cavities 30 being located collectively, multiple through-holes 31 to be the cavities 30 may be formed by, for example, etching or drilling in substantially a plate or a block (e.g., the second substrate 3). For the cavities 30 being located collectively, multiple layers with multiple through-holes to be the cavities 30 may be stacked on one another and joined together.

In the present embodiment, the display device 1 includes the first substrate 2, the second substrate 3, the pixel units 4, and a drive controller 5. In the display device 1, the cavity structure 3k may include the first substrate 2 and the second substrate 3. The first substrate 2 may include a first surface 2a including bottom surfaces 2aa of the cavities 30. The second substrate 3 may be on the first surface 2a. The second substrate 3 may include a second surface 3a facing the first surface 2a, and the third surface 3b as the display surface opposite to the second surface 3a. The second substrate 3 may include the through-holes 31 extending through the second substrate 3 from portions of the second surface 3a corresponding to the bottom surfaces 2aa to the third surface 3b. The through-holes 31 may define inner peripheral surfaces (inner surfaces 31a) of the cavities 30. The first light emitters 41 and the second light emitters 42 may be on the bottom surfaces 2aa exposed by the through-holes 31. This structure produces the effects described below. The cavities 30 with a uniform shape and a uniform depth can be collectively formed in the second substrate 3 by, for example, photolithography including etching. The cavities 30 have the depth adjustable by adjusting the thickness of the second substrate 3. A thicker second substrate 3 facilitates formation of deeper cavities 30 in the second substrate 3 that allow emission of light outside with higher directivity.

Each first light emitter 41 and the corresponding second light emitter 42 may be on the bottom surface 2aa exposed by the through-hole 31, and may be symmetrical to each other about the center of the bottom surface 2aa as viewed in plan. This may further reduce non-uniformity in display images. Being symmetrical may include being symmetrical about a line and being rotationally symmetrical.

Each bottom surface 2aa may have a shape with a major axis and a minor axis, such as a rectangle or an ellipse, as viewed in plan. In this case, the first light emitter 41 and the second light emitter 42 may be symmetrical to each other about the center of the bottom surface 2aa in its major axis as viewed in plan. This may further reduce non-uniformity in display images.

The first light emitter 41 and the second light emitter 42 may include emission portions symmetrical to each other about the center of the bottom surface 2aa as viewed in plan. This may further reduce non-uniformity in display images specifically when the first light emitter 41 includes the emission portion located away from the middle of the first light emitter 41 as viewed in plan. The same applies to the emission portion of the second light emitter 42. Each of the first light emitter 41 and the second light emitter 42 may include the emission portion located away from its middle, or specifically, located adjacent to the center of the bottom surface 2aa as viewed in plan. This may further reduce non-uniformity in display images.

The first light emitter 41 and the second light emitter 42 may have different emission efficiencies. In this case, the one of the first light emitter 41 and the second light emitter 42 with the lower emission efficiency may be at the center of the bottom surface 2aa, and another with the higher emission efficiency may be located off the center of the bottom surface 2aa as viewed in plan. This reduces non-uniformity in display images. For example, an LED that emits red light (with a wavelength of 640 to 770 nm) is more likely to have a lower emission efficiency at a longer wavelength. Thus, an LED with a longer center wavelength of 640 to 770 nm may be at the center of the bottom surface 2aa.

The first substrate 2 includes a main surface, or specifically, the first surface 2a. The first substrate 2 may be, for example, triangular, square, rectangular, hexagonal, or in any other shape as viewed in plan (in other words, as viewed in a direction perpendicular to the first surface 2a).

The first substrate 2 is made of, for example, a glass material, a ceramic material, a resin material, a metal material, or a semiconductor material. Examples of the glass material used for the first substrate 2 include borosilicate glass, crystallized glass, quartz, and soda glass. Examples of the ceramic material used for the first substrate 2 include alumina (Al₂O₃), aluminum nitride (AlN), silicon nitride (Si₃N₄), zirconia (ZrO₂), and silicon carbide (SiC). Examples of the resin material used for the first substrate 2 include an epoxy resin, a polyimide resin, and a polyamide resin. Examples of the metal material used for the first substrate 2 include aluminum (Al), titanium (Ti), beryllium (Be), magnesium (Mg) (specifically, high-purity magnesium with Mg content of 99.95% or higher), zinc (Zn), tin (Sn), copper (Cu), iron (Fe), chromium (Cr), nickel (Ni), and silver (Ag). The metal material used for the first substrate 2 may be an alloy material. Examples of the alloy material used for the first substrate 2 include an iron alloy mainly containing iron (a Fe—Ni alloy, a Fe—Ni—Co (cobalt) alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first substrate 2 include silicon (Si), germanium (Ge), and gallium arsenide (GaAs).

The first substrate 2 may include a single layer of, for example, the glass material, the ceramic material, the resin material, the metal material, or the semiconductor material described above, or may be a stack of multiple layers of any of these materials. For the first substrate 2 being a stack of multiple layers, the layers may be made of the same or different materials.

As illustrated in, for example, FIG. 2, the second substrate 3 is located on the first surface 2a of the first substrate 2. The second substrate 3 is, for example, a plate or a block. The second substrate 3 includes the second surface 3a facing the first surface 2a of the first substrate 2, and the third surface 3b opposite to the second surface 3a. The third surface 3b is the display surface of the display device 1 for outputting image light. The second substrate 3 may be, for example, triangular, square, rectangular, hexagonal, or in any other shape as viewed in plan. The first substrate 2 and the second substrate 3 may have the same shape as viewed in plan.

As illustrated in, for example, FIGS. 1 and 2, the second substrate 3 includes the through-holes 31 extending through the second substrate 3 from the second surface 3a to the third surface 3b. The through-holes 31 expose multiple portions (hereafter also referred to as element-mounting portions) 2aa of the first surface 2a. The element-mounting portions 2aa are also the bottom surfaces of the cavities 30.

Each through-hole 31 may have a section parallel to the third surface 3b being, for example, square, rectangular, circular, or in any other shape. As illustrated in, for example, FIG. 1, each through-hole 31 includes an opening in the third surface 3b that may have an outer edge surrounding the outer edge of the corresponding element-mounting portion 2aa as viewed in plan. As illustrated in, for example, FIG. 2, each through-hole 31 may have a section parallel to the second surface 3a gradually enlarging from the second surface 3a toward the third surface 3b. This facilitates output of light emitted from the pixel units 4 from the display device 1.

The second substrate 3 is made of, for example, a glass material, a ceramic material, a resin material, a metal material, or a semiconductor material. Examples of the glass material used for the second substrate 3 include borosilicate glass, crystallized glass, quartz, and soda glass. Examples of the ceramic material used for the second substrate 3 include alumina, aluminum nitride, silicon nitride, zirconia, and silicon carbide. Examples of the resin material used for the second substrate 3 include an epoxy resin, a polyimide resin, and a polyamide resin. Examples of the metal material used for the second substrate 3 include aluminum, titanium, beryllium, magnesium (specifically, high-purity magnesium with Mg content of 99.95% or higher), zinc, tin, copper, iron, chromium, nickel, and silver. The metal material used for the second substrate 3 may be an alloy material. Examples of the alloy material used for the second substrate 3 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material for the second substrate 3 include silicon, germanium, and gallium arsenide.

The second substrate 3 may include a single layer of the above metal material, or may be a stack of multiple layers of the above metal material. For the second substrate 3 being a stack of multiple layers, the layers may be made of the same or different materials. The through-holes 31 may be formed by, for example, punching, electroforming (plating), cutting, or laser beam machining. For the second substrate 3 made of a metal material or an alloy material, the through-holes 31 may be formed by, for example, punching or electroforming. For the second substrate 3 made of a semiconductor material, the through-holes 31 may be formed by, for example, photolithography including dry etching.

For the second substrate 3 made of a metal material, an alloy material, or a semiconductor material, insulators 6 made of an electrically insulating material may be located between the first surface 2a of the first substrate 2 and the second surface 3a of the second substrate 3 as illustrated in, for example, FIG. 3. This reduces short-circuiting between electrodes, wiring conductors, or other components on the first surface 2a through the second substrate 3. Examples of the electrically insulating material used for the insulators 6 include silicon oxide and silicon nitride. The insulators 6 may be located on a part of the second surface 3a of the second substrate 3, or may extend across the second surface 3a.

The pixel units 4 are located on the respective element-mounting portions 2aa. Each pixel unit 4 includes the first light emitter 41 and the second light emitter 42 (also collectively referred to as the light emitters 41 and 42). The first light emitter 41 and the second light emitter 42 form a redundant structure. The redundant structure may refer to the first light emitter 41 and the second light emitter 42 each having a similar emission color. For example, the first light emitter 41 and the second light emitter 42 may each have a reddish emission color with an emission wavelength in the range of about 640 to 770 nm. The first light emitter 41 and the second light emitter 42 may each have a greenish emission color with an emission wavelength in the range of about 490 to 555 nm. The first light emitter 41 and the second light emitter 42 may each have a bluish emission color with an emission wavelength in the range of about 430 to 490 nm. The emission wavelength may be a center wavelength or a wavelength range. The wavelength range may be a range with a half or more of the peak in the spectrum.

In some embodiments, the redundant structure may refer to the light emitters having substantially the same emission characteristics as a product. In other words, the first light emitter 41 and the second light emitter 42 may have substantially the same emission characteristics with a margin of error as a product. For example, the first light emitter 41 and the second light emitter 42 may each have an emission wavelength with a margin of error as a product (specifically, about ±10 nm of the center wavelength), and may each have an emission intensity with a margin of error as a product (specifically, about ±30% of the reference luminance) at the same input current. The first light emitter 41 and the second light emitter 42 may be substantially the same with no error as a product. In the display device 1, the first light emitter 41 may be the regular light emitter, and the second light emitter 42 may be the redundant light emitter. In some embodiments, the first light emitter 41 may be the redundant light emitter, and the second light emitter 42 may be the regular light emitter.

The first light emitter 41 and the second light emitter 42 may have emission characteristics that are not within the same range as a product. For example, the first light emitter 41 and the second light emitter 42 may have the emission wavelengths with a difference between them exceeding the margin of error as a product. In this case, for example, the one of the light emitters may have the drive current or the temperature controlled with a correction circuit to correct the emission wavelength and the luminance to be approximate to the emission wavelength and the luminance of another light emitter with a margin of error as a product or to be equal to these.

The light emitters 41 and 42 may be, for example, self-luminous light emitters such as LEDs, organic LEDs (OLEDs), or semiconductor laser diodes (LDs). In the present embodiment, the light emitters 41 and 42 are LEDs. The light emitters 41 and 42 may be micro-LEDs. Each micro-LED mounted on the element-mounting portion 2aa may be rectangular as viewed in plan with each side having a length of about 1 to 100 µm inclusive, or about 5 to 20 µm inclusive.

In the display device 1 according to the present embodiment, the first light emitter 41 and the second light emitter 42 are arranged in the same pattern on each element-mounting portion 2aa. More specifically, in the present embodiment, the display device 1 includes the cavity structure 3k combining the first substrate 2 and the second substrate 3 and including multiple cavities 30. In each cavity 30, the first light emitter 41 and the second light emitter 42 are arranged in the same pattern. Unlike a display device with first and second light emitters 41 and 42 accommodated in the respective first and second cavities separate from each other, the display device 1 eliminates walls separating the first and second cavities and allows the first and second light emitters 41 and 42 to be closer to each other. This increases the pixel density.

First and second cavities accommodating the respective first and second light emitters 41 and 42 may have smaller dimensions to achieve a higher pixel density. The first cavities with smaller dimensions have smaller spaces between the first light emitters 41 and the side walls of the first cavities. The second cavities with smaller dimensions have smaller spaces between the second light emitters 42 and the side walls of the second cavities. The light emitters 41 and 42 and the cavity structure with this structure may be more susceptible to damage in manufacturing the display device and more likely to reduce the manufacturing yield. In the display device 1 according to the present embodiment, the first light emitter 41 and the second light emitter 42 are located in each cavity 30. This structure increases the pixel density while leaving sufficient spaces between the first and second light emitters 41 and 42 and the side walls of the cavities 30.

In one or more embodiments of the present disclosure, the display device 1 may include a drive controller 5 that performs first driving to drive the first light emitters 41 or second driving to drive the second light emitters 42 for the pixel units 4. The drive controller 5 may perform the first driving for a predetermined proportion (e.g., a half) of the pixel units 4, and may perform the second driving for the remaining (e.g., the other half) pixel units 4 among them. This effectively reduces non-uniformity across the entire display images when the first light emitter 41 and the second light emitter 42 are located across the center line of the bottom surface 2aa of each cavity 30 (e.g., the center line parallel to the row direction or to the column direction) as viewed in plan.

The drive controller 5 may perform the first driving for about 30 to 70% of the pixel units 4, and may perform the second driving for the remaining about 70 to 30% of the pixel units 4 among them.

The drive controller 5 may perform the first driving for a predetermined proportion of the pixel units 4 selected randomly, and may perform the second driving for the remaining pixel units 4 selected randomly among them.

The drive controller 5 may change the pixel units 4 for the first driving and the pixel units 4 for the second driving for every one or more frames. This reduces non-uniformity across the entire display images more effectively. The drive controller 5 may change the pixel units 4 for the first driving and the pixel units 4 for the second driving for, but is not limited to, every one to ten frames.

The drive controller 5 may select the pixel units 4 for the first driving and the pixel units 4 for the second driving regularly and alternately. For example, the pixel units 4 may be arranged in a matrix pattern. The one of the first light emitter 41 and the second light emitter 42 may emit light in each pixel unit 4 in one of two adjacent rows of the matrix. Another of the first light emitter 41 and the second light emitter 42 may emit light in each pixel unit 4 in the other row. This reduces non-uniformity across the entire display images more effectively.

In some embodiments, the pixel units 4 may be arranged in a matrix pattern. The one of the first light emitter 41 and the second light emitter 42 may emit light in each pixel unit 4 in one of two adjacent columns of the matrix. Another of the first light emitter 41 and the second light emitter 42 may emit light in each pixel unit 4 in the other column. This reduces non-uniformity across the entire display images more effectively.

In some embodiments, the pixel units 4 may be arranged in a matrix pattern. The one of the first light emitter 41 and the second light emitter 42 may emit light in one of the pixel units 4. Another of the first light emitter 41 and the second light emitter 42 may emit light in each of the two pixel units 4 adjacent to the above pixel unit 4 in the row direction of the matrix, and in each of the two pixel units 4 adjacent to the above pixel unit 4 in the column direction of the matrix. This reduces non-uniformity across the entire display images more effectively.

The drive controller 5 may be incorporated in a drive unit for emission control signal lines including, for example, ICs or LSI circuits in the display device 1. For example, the drive controller 5 may be program software stored in a read-only memory (ROM) or a random-access memory (RAM) in the drive unit. The drive controller 5 may be a drive element or a drive circuit board including, for example, ICs or LSI circuits in the display device 1, or may be a drive element or a drive circuit board separate from the display device 1.

In a display device 1A according to a second aspect of the disclosure, the first and second light emitters 41 and 42 include anode terminals 41a and 42a as first terminals and cathode terminals 41b and 42b as second terminals. The anode terminals 41a and 42a are spaced from the cathode terminals 41b and 42b as viewed in plan. Each of the first and second light emitters 41 and 42 includes the emission portion located away from the middle and adjacent to the anode terminal 41a or 42a or adjacent to the cathode terminal 41b or 42b in the corresponding light emitter 41 or 42. Each cavity 30 includes, on its bottom surface 2aa, an anode electrode 7 as a first electrode connected to the anode terminals 41a and 42a, and a cathode electrode 8 as a second electrode connected to the cathode terminals 41b and 42b. The anode electrode 7 or the cathode electrode 8 corresponding to the anode terminals 41a and 42a or the cathode terminals 41b and 42b located adjacent to the emission portions is in a central portion of the bottom surface 2aa.

The above structure produces the advantageous effects described below. Each of the first light emitter 41 and the second light emitter 42 includes the emission portion located in the central portion of the bottom surface 2aa. This reduces uneven emission of light from each cavity 30 outside when any one of the first light emitter 41 and the second light emitter 42 emits light. This reduces non-uniformity across the entire display images more effectively.

In the display device 1A, the first terminals may be the anode terminals 41a and 42a, the second terminals may be the cathode terminals 41b and 42b, the first electrode may be the anode electrode 7, and the second electrode may be the cathode electrode 8. In this case, the cathode electrode 8 as the second electrode may be located in the central portion of the bottom surface 2aa. The cathode electrode 8, which can readily serve as a common electrode with a predetermined low potential such as a ground potential, is thus located in the central portion of the bottom surface 2aa and used as a common electrode. In some embodiments, the anode electrode 7 as the first electrode may be located in the central portion of the bottom surface 2aa and used as a common electrode.

The central portion of the bottom surface 2aa may be similar in shape to the bottom surface 2aa and may cover about, but is not limited to, 10 to 30% of the area of the bottom surface 2aa.

The display device may include, on the central portion of each bottom surface 2aa, a cathode electrode connected to the first light emitter 41 and another cathode electrode connected to the second light emitter 42. In other words, the first light emitter 41 and the second light emitter 42 may be connected to different cathode electrodes, instead of a common electrode. In this case, the first light emitter 41 and the second light emitter 42 may have individual cathode voltages. The structure in this embodiment may be similarly used when the anode electrode is located in the central portion of each bottom surface 2aa.

The first substrate 2 includes the first electrodes (anode electrodes) 7 and the second electrodes (cathode electrodes) 8 located on the element-mounting portions 2aa. In the present embodiment, as illustrated in, for example, FIGS. 1 and 2, the display device includes one cathode electrode 8 as a common electrode in the central portion of each element-mounting portion 2aa, and two anode electrodes 7 on a peripheral portion of each element-mounting portion 2aa across the cathode electrode 8. The cathode electrode 8 is electrically connected to both the cathode terminal 41b of the first light emitter 41 and the cathode terminal 42b of the second light emitter 42. One of the two anode electrodes 7 is electrically connected to the anode terminal 41a of the first light emitter 41. Another anode electrode 7 is electrically connected to the anode terminal 42a of the second light emitter 42. In some embodiments, the display device 1A may include one anode electrode 7 in the central portion of each element-mounting portion 2aa, and two cathode electrodes 8 on a peripheral portion of each element-mounting portion 2aa across the anode electrode 7.

The display device 1A may drive a different one of the first light emitter 41 and the second light emitter 42 for each pixel unit 4. This reduces non-uniformity across the entire display images still more effectively. The display device 1A may have the same or similar features as in the above embodiments for the display device 1.

The light emitters 41 and 42 may be connected to the anode electrodes 7 and the cathode electrodes 8 by flip-chip connection. The light emitters 41 and 42 may be electrically and mechanically connected to the anode electrodes 7 and the cathode electrodes 8 by flip-chip connection using conductive connectors, such as solder balls, metal bumps, or a conductive adhesive. The light emitters 41 and 42 may be electrically connected to the anode electrodes 7 and the cathode electrodes 8 using conductive connectors such as bonding wires.

For the first substrate 2 made of a metal material or a semiconductor material, an insulating layer of, for example, silicon oxide or silicon nitride may be located on at least the first surface 2a of the first substrate 2, and the light emitters 41 and 42 may be located on the insulating layer. This reduces electrical short-circuiting between the anode terminals 41a and 42a and the cathode terminals 41b and 42b of the light emitters 41 and 42.

The anode electrodes 7 and the cathode electrodes 8 are connected to the drive controller 5. The drive controller 5 controls, for example, the emission or non-emission state and the light intensity of each of the light emitters 41 and 42. The drive controller 5 may be located on the first substrate 2. For example, the drive controller 5 may be located on the first main surface 2a of the first substrate 2, or may be located on the second main surface 2b of the first substrate 2. The drive controller 5 may be between multiple insulating layers of, for example, silicon oxide or silicon nitride located on the first substrate 2.

The drive controller 5 in the display device 1A may change the pixel units 4 for the first driving and the pixel units 4 for the second driving for every one or more frames. This reduces non-uniformity across the entire display images more effectively. The drive controller 5 may change the pixel units 4 for the first driving and the pixel units 4 for the second driving for, but is not limited to, every one to ten frames.

FIG. 10 is a schematic block diagram of the display device 1 (1A) according to the embodiment of the present disclosure. The display device 1 (1A) includes a composite substrate 103, the pixel units 4, and the drive controller 5. The substrate 103 includes the first substrate 2 and the second substrate 3. The pixel units 4 are arranged on a first main surface 103a of the substrate 103 in a matrix in a first direction X and a second direction Y orthogonal to the first direction X. The drive controller 5 controls each pixel unit 4 to receive an image signal from an image signal generator 105 and to emit light with luminance corresponding to the received image signal.

The display device includes, on the first main surface 103a, n × m pixel units 4 (n is the number of rows, m is the number of columns, and n and m are positive integers) each including a pixel circuit as an emission controller and arranged in a matrix at a predetermined pixel pitch. The display device also includes, on the first main surface 3a, n gate signal lines G1 to Gn, m source signal lines S1 to Sm, a gate signal generator 101, and a drive circuit 102. The pixel units 4 may have a pixel pitch of, for example, about 50 to 500 µm, about 100 to 400 µm, or about 380 µm, or may have a pixel density of at least 300 pixels per inch. Each pixel unit 4 includes the anode electrode 7, the cathode electrode 8, the light emitters 41 and 42 electrically connected to these electrodes 7 and 8, and a drive thin-film transistor (TFT) for controlling, for example, the luminance and the lighting or non-lighting state of each of the light emitters 41 and 42. Each pixel unit 4 may include a pixel circuit including a complementary metal-oxide-semiconductor (CMOS) transfer gate, an inverter logic circuit (inverter), or a NOR circuit.

The first light emitter 41 and the second light emitter 42 included in a pixel unit 4 may have an emission characteristic different from an emission characteristic of the first light emitter 41 and the second light emitter 42 included in another pixel unit 4. For example, the first light emitter 41 and the second light emitter 42 in a pixel unit 4 may emit red light, and the first light emitter 41 and the second light emitter 42 in another pixel unit 4 may emit green or blue light.

Each pixel unit 4 may include a subpixel for emitting red light, a subpixel for emitting green light, and a subpixel for emitting blue light. The subpixel for emitting red light includes a red light emitter such as a red LED. The subpixel for emitting green light includes a green light emitter such as a green LED. The subpixel for emitting blue light includes a blue light emitter such as a blue LED. For example, each pixel may include a set of red, green, and blue subpixels arranged in the column direction or in the row direction. The first light emitter 41 and the second light emitter 42 may be identical red light emitters. The first light emitter 41 and the second light emitter 42 may be identical green light emitters. The first light emitter 41 and the second light emitter 42 may be identical blue light emitters.

The pixel units 4 are in a selected state in response to gate signals (pixel selection signals) provided from the gate signal generator 101 through the n gate signal lines G1 to Gn. The pixel units 4 in the selected state receive source signals (image signals) provided from the drive circuit 102 through the m source signal lines S1 to Sm. Each drive TFT has a drain electrode connected to the light emitters 41 and 42, and a gate electrode for receiving a gate signal through any one of the gate signal lines G1 to Gn. The drive TFT receiving the gate signal at its gate electrode is turned on (the drive TFT is conductive between the source and the drain). The drive TFT in an on-state receives a source signal at its source electrode from the drive circuit 102 through any one of the source signal lines S1 to Sm. The drive TFT then provides the source signal to the light emitters 41 and 42 connected to the drain electrode as a drain current. The light emitters 41 and 42 receive the source signal (drain current) and emit light with luminance corresponding to the potential of the source signal. Each light emitter has the emission intensity controlled in accordance with the drain current to express gradations.

The light emitters 41 and 42 are self-luminous light emitters such as LEDs, organic electroluminescent (EL) elements, or semiconductor LDs. Each of the light emitters 41 and 42 emits light with luminance corresponding to the level of the current flowing from the anode to the cathode.

The drive controller 5 includes, for example, a TFT and a wiring conductor. The TFT may include a semiconductor film (or a channel) of, for example, amorphous silicon (a-Si) or low-temperature polycrystalline silicon (LTPS). The TFT may include three terminals, or specifically, a gate electrode, a source electrode, and a drain electrode. The TFT serves as a switching element that switches conduction and non-conduction between the source electrode and the drain electrode based on the voltage applied to the gate electrode. The drive controller 5 may be formed with a thin film formation method such as chemical vapor deposition (CVD).

The drive controller 5 controls each pixel unit 4. The drive controller 5 performs the first driving to drive the first light emitter 41 or the second driving to drive the second light emitter 42 for each pixel unit 4. The first driving causes the first light emitter 41 to emit light and causes the second light emitter 42 not to emit light. The second driving causes the second light emitter 42 to emit light and causes the first light emitter 41 not to emit light.

The drive controller 5 performs the first driving for a predetermined proportion (e.g., a half) of the pixel units 4, and performs the second driving for the remaining (e.g., the other half) pixel units 4 among them. The term half herein is not limited to being precisely half. The drive controller 5 may perform the first driving for about a half of the pixel units 4, and may perform the second driving for the remaining pixel units 4 among them. The drive controller 5 may perform the first driving for, for example, 30 to 70% of the pixel units 4, and may perform the second driving for the remaining pixel units 4 among them.

In the display device 1 or 1A according to the present embodiment, one or more pixel units 4 with defective first light emitters 41 are included in the remaining half of the pixel units for the second driving. In other words, the display device 1 or 1A causes the second light emitters 42 to emit light in one or more pixel units 4 that include the first light emitters 41 in a non-emission state. The display device 1 thus improves the manufacturing yield.

In the present embodiment, the display device 1 or 1A performs the first driving for a half of the pixel units 4, and performs the second driving for the remaining half of the pixel units 4 among them. The display device 1 or 1A has less noticeable non-uniformity across the entire display images that may be caused by a change in intensity distribution of light output from the display device through the pixel units 4 when the light emitters to be driven are changed between the first light emitters 41 and the second light emitters 42. The display device 1 or 1A thus improves the image quality.

As illustrated in, for example, FIG. 1, the through-holes 31 may be arranged in a matrix in a first direction D1 and a second direction D2 intersecting with the first direction D1. The pixel units 4 may be arranged in a matrix in the first direction D1 and the second direction D2. The first direction D1 and the second direction D2 may or may not be orthogonal to each other as viewed in plan.

For the pixel units 4 arranged in a matrix, as illustrated in, for example, FIG. 4, the drive controller 5 may perform the first driving for pixel units 4 in the one of two adjacent rows in a matrix M of pixel units 4, and may perform the second driving for pixel units 4 in another row. In other words, the drive controller 5 may switch between the first driving and the second driving for each row of the matrix M. Thus, pixel units 4 in the half for the first driving are located alternately with the remaining pixel units 4 in the other half for the second driving in the row direction. This allows still less noticeable non-uniformity in display images, improving the image quality.

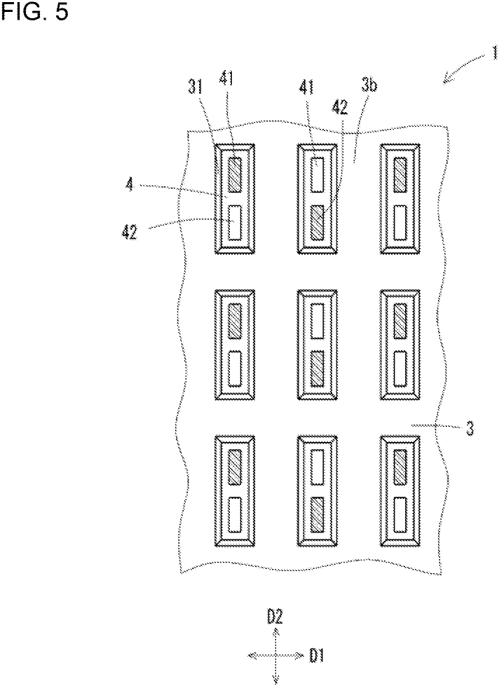

As illustrated in, for example, FIG. 5, the drive controller 5 may perform the first driving for pixel units 4 in the one of two adjacent columns of the matrix M, and may perform the second driving for pixel units 4 in another column. In other words, the drive controller 5 may switch between the first driving and the second driving for each column of the matrix M. Thus, pixel units 4 in the half for the first driving are located alternately with the remaining pixel units 4 in the other half for the second driving in the column direction. This allows still less noticeable non-uniformity in display images, improving the image quality.

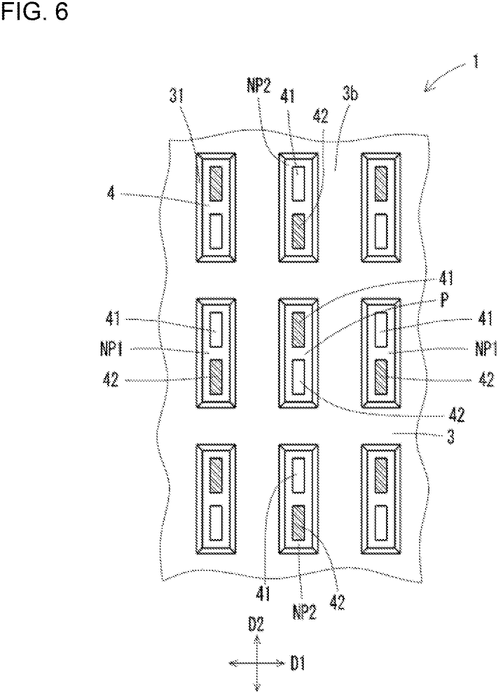

As illustrated in, for example, FIG. 6, when performing the one of the first driving and the second driving for a pixel unit P, the drive controller 5 may perform-another of the first driving and the second driving for two pixel units NP1 adjacent to the pixel unit P in the first direction D1 and for two pixel units NP2 adjacent to the pixel unit P in the second direction D2. In other words, the drive controller 5 may perform the first driving for one of two sets of staggered pixel units in the matrix M, and may perform the second driving for another set of pixel units. Thus, pixel units 4 in the half for the first driving are located alternately with the remaining pixel units 4 in the other half for the second driving in the row, column, and oblique directions. This allows still less noticeable non-uniformity in display images, improving the image quality.

In the display device 1, each pixel unit 4 may include multiple subpixel units 4R, 4G, and 4B. The subpixel units 4R, 4G, and 4B may be located on the corresponding element-mounting portions 2aa. The subpixel units 4R, 4G, and 4B may include a subpixel unit 4R including light emitters 41 and 42 that emit red light, a subpixel unit 4G including light emitters 41 and 42 that emit green light, and a subpixel unit 4B including light emitters 41 and 42 that emit blue light. This allows the display device 1 to display full-color gradations.

Each pixel unit 4 may include, in addition to the subpixel units 4R, 4G, and 4B, at least one of a subpixel unit including light emitters 41 and 42 that emit yellow light or a subpixel unit including light emitters 41 and 42 that emit white light. This improves the color rendering and color reproduction of the display device 1. The subpixel unit 4R may include, instead of the light emitters 41 and 42 that emit red light, light emitters 41 and 42 that emit orange, red-orange, red-violet, or violet light. The subpixel unit 4G may include, instead of the light emitters 41 and 42 that emit green light, light emitters 41 and 42 that emit yellow-green light.

The drive controller 5 may perform one of the first driving and the second driving for all the subpixel units in each pixel unit 4. The drive controller 5 may perform the one of the first driving and the second driving for at least one subpixel unit in each pixel unit 4, and may perform another of the first driving and the second driving for at least another subpixel in the pixel unit 4.

In the display device 1, light emitted from the light emitters 41 and 42 may be reflected on the inner surfaces 31a of the through-holes 31. This allows substantially collimated light to be output through the through-holes 31. The display device 1 thus outputs image light with increased directivity and improves the image quality.

In the display device 1 or 1A, the second substrate 3 may be thicker than the first substrate 2. The thicker second substrate 3 includes the through-holes 31 with the inner surfaces 31a that can reflect light emitted from the light emitters 41 and 42 at least once. This allows substantially collimated light to be output through the through-holes 31. The display device 1 or 1A thus outputs light with increased directivity. To allow light emitted from the light emitters 41 and 42 to be reflected on the inner surfaces 31a of the through-holes 31 at least once, the display device 1 or 1A may have parameters determined as appropriate based on, for example, the intensity distribution of light emitted from the light emitters 4. The parameters may include the thickness of the second substrate 3, the shape of each through-hole 31, and the dimensional ratio between each through-hole 31 and each light emitter 4.

The through-holes 31 in the second substrate 3 may include mirror-like inner surfaces 31a. This allows light emitted from the light emitters 41 and 42 to be reflected on the inner surfaces 31a with an increased reflectance and a reduced loss. The display device thus outputs light emitted from the light emitters 41 and 42 outside more efficiently and displays high-luminance images.

The inner surfaces 31a of the through-holes 31 may undergo, for example, electrolytic polishing or chemical polishing to have a mirror finish. The inner surfaces 31a may have a surface roughness Ra of, for example, about 0.01 to 0.1 µm. The inner surfaces 31a may have a reflectance of visible light of, for example, about 85 to 95%.

As illustrated in, for example, FIG. 4, the display device 1 or 1A may include a light reflective film 9 on the inner surfaces 31a of the through-holes 31. This allows light emitted from the light emitters 41 and 42 to be reflected in the through-holes 31 with an increased reflectance and a reduced loss independently of, for example, the material for the second substrate 3 or the surface roughness Ra of the inner surfaces 31a. The display device 1 or 1A thus outputs light emitted from the light emitters 41 and 42 outside more efficiently and displays high-luminance images.

The light reflective film 9 may be made of, for example, a metal material. Examples of the metal material used for the light reflective film 9 include aluminum, silver, and gold.

The light reflective film 9 may be formed on the inner surfaces 31a of the through-holes 31 by a thin film formation method such as CVD, vapor deposition, or plating, or by a thick film formation method such as firing and solidifying a resin paste containing particles of, for example, aluminum, silver, or gold. The light reflective film 9 may be formed on the inner surfaces 31a of the through-holes 31 by bonding a film containing, for example, aluminum, silver, gold, or an alloy of any of these metals. A protective film may be located on the outer surface of the light reflective film 9 to reduce oxidation of the light reflective film 9, which may cause a decrease in reflectance.

The second substrate 3 may include the third surface 3b roughened by, for example, blasting. The roughened third surface 3b has a larger surface area and dissipates heat more easily. The roughened third surface 3b also reflects external light diffusely. The display device 1 or 1A thus outputs image light with less interference with reflected external light, avoiding lowering the image quality.

As illustrated in, for example, FIGS. 2 and 3, the display device 1 or 1A may include a light absorbing film 10 on the third surface 3b of the second substrate 3. The light absorbing film 10 absorbs external light incident on the third surface 3b. In the display device 1 or 1A according to the present variation, the third surface 3b reduces reflection of external light. The display device 1 or 1A thus outputs image light with less interference with reflected external light, avoiding lowering the image quality.

The light absorbing film 10 may be formed by, for example, applying a photocuring or a thermosetting resin material containing a light absorbing material to the third surface 3b of the second substrate 3 and curing the material. The light absorbing material may be, for example, an inorganic pigment. Examples of the inorganic pigments may include carbon pigments such as carbon black, nitride pigments such as titanium black, and metal oxide pigments such as Cr—Fe—Co, Cu—Co—Mn (manganese), Fe—Co—Mn, and Fe—Co—Ni—Cr pigments.

The light absorbing film 10 may include a rough surface that absorbs incident light. For example, the light absorbing film 10 may be a black film formed by mixing a black pigment such as carbon black in a base material such as a silicone resin and by roughening the surface of the black film. This greatly increases the light absorbing effect. The rough surface may have an arithmetic mean roughness of about 10 to 50 µm or about 20 to 30 µm. The rough surface may be formed by, for example, transferring.

As illustrated in, for example, FIGS. 2 and 3, the display device 1 or 1A may include multiple transparent members 11. The transparent members 11 are located in the through-holes 31 and seal the light emitters 41 and 42. The transparent members 11 may be in contact with the surfaces of the light emitters 41 and 42 and in contact with the inner surfaces 31a of the through-holes 31.

The transparent members 11 are made of, for example, a transparent resin material. Examples of the transparent resin material used for the transparent members 11 include a fluororesin, a silicone resin, an acrylic resin, a polycarbonate resin, and a polymethyl methacrylate resin.

The through-holes 31 filled with the transparent members 11 reduce thermal resistance on the heat dissipation paths (or the heat transfer paths) from the light emitters 41 and 42 to the second substrate 3, as compared with the through-holes 31 filled with gas such as air. The display device 1 or 1A according to the present variation thus effectively dissipates heat from the light emitters 41 and 42 outside through the second substrate 3. The display device 1 or 1A according to the present variation effectively allows the light emitters 41 and 42 to have the emission efficiencies less susceptible to their heat, and thus displays high-luminance images.

The display device 1 or 1A with the transparent members 11 reduces the likelihood of the light emitters 41 and 42 being misaligned or separate from the element-mounting portions 2aa after a long use. The display device 1 or 1A thus has higher long-term reliability.

Each transparent member 11 may include a body 11a made of a transparent resin material and multiple insulating particles 11b dispersed in the body 11a.

Examples of the transparent resin material used for the bodies 11a include a fluororesin, a silicone resin, an acrylic resin, a polycarbonate resin, and a polymethyl methacrylate resin. The insulating particles 11b are made of, for example, a glass material or a ceramic material. Examples of the glass material used for the insulating particles 11b include borosilicate glass, crystallized glass, quartz, and soda glass. Examples of the ceramic material used for the insulating particles 11b include alumina, aluminum nitride, and silicon nitride. The insulating particles 11b may be made of a glass material with a greater refractive index than the bodies 11a, or a ceramic material with a high reflectance of visible light.

The insulating particles 11b scatter external light incident on the transparent members 11 and partly reflect the external light outside the display device. The insulating particles 11b reduce the likelihood that external light incident on the transparent members 11 is reflected in the through-holes 31 and interferes with light emitted from the light emitters 41 and 42. The display device 1 or 1A with the transparent members 11 including the bodies 11a and the insulating particles 11b thus outputs image light with less interference with external light, avoiding lowering the image quality.

The transparent members 11 may be formed by filling the through-holes 31 with a transparent resin material containing dispersed insulating particles 11b and by curing the material. In manufacturing the display device 1 or 1A, a transparent resin material containing dispersed insulating particles 11b may be placed and cured between the first surface 2a of the first substrate 2 and the second surface 3a of the second substrate 3 before the first substrate 2 and the second substrate 3 are connected. The insulating particles 11b between the first surface 2a of the first substrate 2 and the second surface 3a of the second substrate 3 reduce short-circuiting between the second substrate 3 and components on the first surface 2a such as the anode electrodes 7, the cathode electrodes 8, or wiring conductors. This structure may eliminate the insulators 6 between the first surface 2a of the first substrate 2 and the second surface 3a of the second substrate 3.

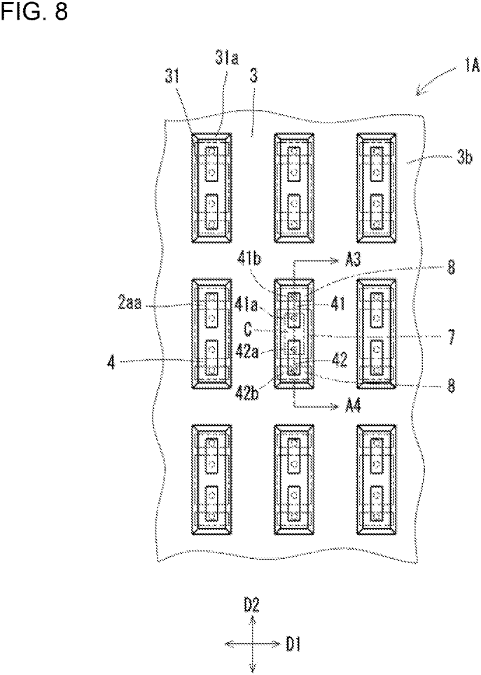

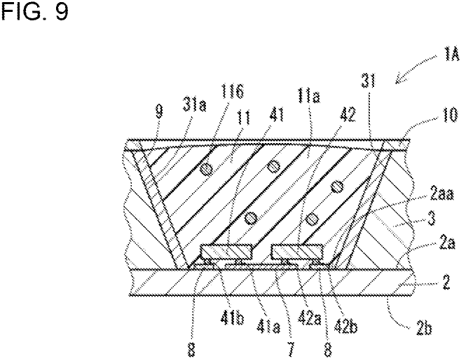

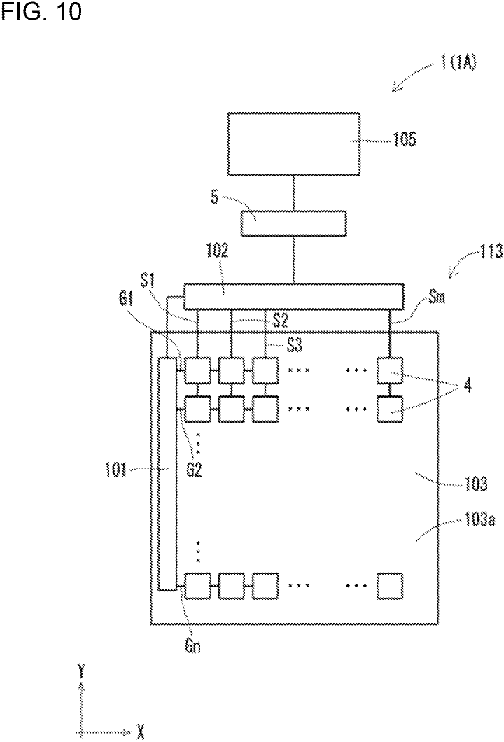

A display device according to another embodiment of the present disclosure will now be described in detail. FIG. 8 is a schematic plan view of a display device according to another embodiment of the present disclosure. FIG. 9 is a cross-sectional view taken along line A3-A4 in FIG. 8. FIG. 8 does not illustrate transparent members, a light reflective film, or a light absorbing film.

In the present embodiment, the display device 1A basically has the same structure as the display device 1 in the embodiment described above except for the structure of the pixel units 4 and the control performed by the drive controller 5. The same or similar components as those of the display device 1 are given the same reference numerals and will not be described in detail.

In the display device 1A according to the present embodiment, each pixel unit 4 includes a two-terminal light emitter 41 having an anode terminal 41a and a cathode terminal 41b, and includes a two-terminal light emitter 42 having an anode terminal 42a and a cathode terminal 42b. Each of the light emitters 41 and 42 is a flip-chip LED connected to the anode electrode 7 and the cathode electrode 8 on the element-mounting portion 2aa by flip-chip connection. In the present embodiment, the light emitters 41 and 42 are flip-chip micro-LEDs.

In the display device 1A, as illustrated in, for example, FIGS. 8 and 9, the anode terminal 41a of the first light emitter 41 and the anode terminal 42a of the second light emitter 42 are located in a central portion C of each element-mounting portion 2aa as viewed in plan. The central portion C is a part of the element-mounting portion 2aa and includes the centroid of the element-mounting portion 2aa as viewed in plan.

As illustrated in, for example, FIGS. 8 and 9, the display device 1A may include one anode electrode 7 in the central portion C of each element-mounting portion 2aa, and two cathode electrodes 8 on a peripheral portion of each element-mounting portion 2aa across the anode electrode 7. The anode electrode 7 may be electrically connected to both the anode terminal 41a of the first light emitter 41 and the anode terminal 42a of the second light emitter 42. One of the two cathode electrodes 8 may be electrically connected to the cathode terminal 41b of the first light emitter 41. The other cathode electrode 8 may be electrically connected to the cathode terminal 42b of the second light emitter 42.

The drive controller 5 controls each pixel unit 4. The drive controller 5 performs the first driving to drive the first light emitter 41 or the second driving to drive the second light emitter 42 for each pixel unit 4. The drive controller 5 may perform one of the first driving and the second driving for each pixel unit 4.

For the light emitters 41 and 42 being flip-chip LEDs, smaller light emitters 41 and 42 have lower emission intensities in areas adjacent to their cathode terminals 41b and 42b, and have higher emission intensities in areas adjacent to their anode terminals 41a and 42a. In the display device 1A, the anode terminals 41a and the anode terminals 42a are both located in the central portions C as viewed in plan. In other words, in the display device 1A, the pixel units 4 include areas with high emission intensities located in the central portions C of the element-mounting portions 2aa both when the first light emitters 41 are driven and when the second light emitters 42 are driven. The display device 1A thus reduces non-uniformity in the intensity distribution of light emitted outside from the pixel units 4 independently of whether the first light emitters 41 are driven or the second light emitters 42 are driven.

The drive controller 5 controls each pixel unit 4. The drive controller 5 performs the first driving to drive the first light emitter 41 or the second driving to drive the second light emitter 42 for each pixel unit 4. The first driving is the control to cause the first light emitter 41 to emit light and to cause the second light emitter 42 not to emit light. The second driving is the control to cause the second light emitter 42 to emit light and to cause the first light emitter 41 not to emit light. The drive controller 5 may perform one of the first driving and the second driving for each pixel unit 4.

In the display device 1A according to the present embodiment, one or more pixel units 4 with defective first light emitters 41 are included in the pixel units 4 for the second driving. In other words, the display device 1A causes the second light emitters 42 to emit light in one or more pixel units 4 that include the first light emitters 41 in a non-emission state. The display device 1A thus improves the manufacturing yield.

In the display device 1A, the pixel units 4 include areas with high emission intensities located in the central portions C of the element-mounting portions 2aa. The display device 1A thus reduces non-uniformity in the intensity of light emitted outside from the pixel units 4 independently of whether the first light emitters 41 are driven or the second light emitters 42 are driven. The display device 1A outputs image light with reduced non-uniformity in the emission intensity distribution. This reduces non-uniformity in display images and improves the image quality.

The drive controller 5 may perform the first driving for a half of the pixel units 4, and may perform the second driving for the remaining half of the pixel units 4 among them. This effectively reduces non-uniformity in display images and improves the image quality. The term half herein is not limited to being precisely half. The drive controller 5 may perform the first driving for about a half of the pixel units 4, and may perform the second driving for the remaining pixel units 4 among them. The drive controller 5 may perform the first driving for, for example, 30 to 70% of the pixel units 4, and may perform the second driving for the remaining pixel units 4 among them.

As illustrated in, for example, FIG. 8, the through-holes 31 may be arranged in a matrix in the first direction D1 and the second direction D2 intersecting with the first direction D1. The pixel units 4 may be arranged in a matrix in the first direction D1 and the second direction D2. The first direction D1 and the second direction D2 may or may not be orthogonal to each other as viewed in plan.

For the pixel units 4 arranged in a matrix, as illustrated in, FIG. 4, the drive controller 5 may perform the first driving for pixel units 4 in the one of two adjacent rows in a matrix M of pixel units 4, and may perform the second driving for pixel units 4 in another row. In other words, the drive controller 5 may switch between the first driving and the second driving for each row of the matrix M. Thus, pixel units 4 in the half for the first driving are located alternately with the remaining pixel units 4 in the other half for the second driving in the row direction. This effectively reduces non-uniformity in display images and improves the image quality.

As illustrated in FIG. 5, the drive controller 5 may perform the first driving for pixel units 4 in the one of two adjacent columns of the matrix M, and may perform the second driving for pixel units 4 in another column. Thus, pixel units 4 in the half for the first driving are located alternately with the remaining pixel units 4 in the other half for the second driving in the column direction. This effectively reduces non-uniformity in display images and improves the image quality.

When performing the one of the first driving and the second driving for a pixel unit P, the drive controller 5 may perform another of the first driving and the second driving for the two pixel units NP1 adjacent to the pixel unit P in the first direction D1 and for the two pixel units NP2 adjacent to the pixel unit P in the second direction D2, as illustrated in FIG. 6. Thus, pixel units 4 in the half for the first driving are located alternately with the remaining pixel units 4 in the other half for the second driving in the row, column, and oblique directions. This effectively reduces non-uniformity in display images and improves the image quality.

As described above, in the display device according to one or more aspects of the present disclosure, each pixel unit includes the redundant structure including the first light emitter and the second light emitter, one of which is redundant. This improves the manufacturing yield. In the display device according to the first aspect of the disclosure, a different one of the first light emitter and the second light emitter is driven for each pixel unit. This reduces non-uniformity in display images. In the display device according to the second aspect of the disclosure, the first electrode or the second electrode corresponding to the first terminal or the second terminal adjacent to the emission portion is located in the central portion of the bottom surface of each cavity defining a pixel unit. This reduces non-uniformity in display images.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises. For example, multiple display devices 1 or 1A according to any of the embodiments of the present disclosure may be joined together to form a composite display device (multi-display) by joining the side portions of adjacent display devices with, for example, an adhesive or screws.

### INDUSTRIAL APPLICABILITY

The display device according to one or more embodiments of the present disclosure can be used in various electronic devices. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

REFRENCE SIGNS

| | |
|---|---|
| 1, 1A | Display device |
| 2 | First substrate |
| 2A | First main surface (first surface) |
| 2AA | Portion (first surface) |
| 2B | Second main surface |
| 3 | Second substrate |
| 3A | Second surface |
| 3B | Third surface |
| 3K | Cavity structure |
| 4 | Pixel unit |
| 5 | Drive controller |
| 6 | Insulator |
| 7 | Anode electrode (first electrode) |
| 8 | Cathode electrode (second electrode) |
| 9 | Light reflective film |
| 10 | Light absorbing |
| 11 | Transparent member |
| 11A | Body |
| 11B | Insulting particle |
| 4R, 4G, 4B | Subpixel unit |
| 30 | Cavity |
| 31 | Through-hole |
| 31A | Inner surface (inner peripheral surface of cavity) |
| 41 | First light emitter |
| 41A | Anode terminal (first terminal) |
| 41B | Cathode terminal (second terminal) |
| 42 | Second lighter emitter |
| 42A | Anode terminal (first terminal) |
| 42B | Cathode terminal (second terminal) |

1. A display device, comprising:
a cavity structure including a display surface and a plurality of cavities in the display surface; and
a plurality of pixel units, each pixel unit of the plurality of pixel units including a first light emitter and a second light emitter located in a corresponding cavity of the plurality of cavities, the first light emitter and the second light emitter being arranged in a same pattern in each cavity of the plurality of cavities, the each pixel unit of the plurality of pixel units including a redundant structure configured to cause one of the first light emitter and the second light emitter to be driven to emit light,
wherein the first light emitter and the second light emitter are different in that they are driven according to the each pixel unit.

2. The display device according to claim 1, wherein
the cavity structure includes
a first substrate including a first surface, the first surface including a plurality of bottom surfaces of the respective plurality of cavities, and
a second substrate on the first surface, the second substrate including a second surface facing the first surface and a third surface as the display surface opposite to the second surface, the second substrate including a plurality of through-holes extending through the second substrate from portions of the second surface corresponding to the plurality of bottom surfaces to the third surface, the plurality of through-holes defining inner peripheral surfaces of the respective plurality of cavities, and
the first light emitter and the second light emitter are on a corresponding bottom surface of the plurality of bottom surfaces exposed by the plurality of through-holes.

3. The display device according to claim 1, further comprising:
a drive controller configured to perform first driving to drive the first light emitter or second driving to drive the second light emitter for the each pixel unit of the plurality of pixel units,
wherein the drive controller performs the first driving for a predetermined proportion of the plurality of pixel units, and performs the second driving for the remaining pixel units among the plurality of pixel units.

4. The display device according to claim 1, further comprising:
a drive controller configured to perform first driving to drive the first light emitter or second driving to drive the second light emitter for each of the plurality of pixel units,
wherein the drive controller changes, for every one or more frames, pixel units of the plurality of pixel units for the first driving and pixel units of the plurality of pixel units for the second driving.

5. The display device according to claim 1, wherein
the plurality of pixel units is arranged in a matrix, and
the one of the first light emitter and the second light emitter emits light in each of pixel units of the plurality of pixel units in one of two adjacent rows of the matrix, and another of the first light emitter and the second light emitter emits light in each of pixel units of the plurality of pixel units in another of the two adjacent rows.

6. The display device according to claim 1, wherein
the plurality of pixel units is arranged in a matrix, and
the one of the first light emitter and the second light emitter emits light in each of pixel units of the plurality of pixel units in one of two adjacent columns of the matrix, and another of the first light emitter and the second light emitter emits light in each of pixel units of the plurality of pixel units in another of the two adjacent columns.

7. The display device according to claim 1, wherein
the plurality of pixel units is arranged in a matrix, and
the one of the first light emitter and the second light emitter emits light in a pixel unit of the plurality of pixel units, and another of the first light emitter and the second light emitter emits light in each of two pixel units of the plurality of pixel units adjacent to the pixel unit in a row direction of the matrix and in each of two pixel units of the plurality of pixel units adjacent to the pixel unit in a column direction of the matrix.

8. The display device according to claim 1, wherein
the first light emitter and the second light emitter included in a pixel unit of the plurality of pixel units have an emission characteristic different from an emission characteristic of the first light emitter and the second light emitter included in another pixel unit of the plurality of pixel units.

9. A display device, comprising:
a cavity structure including a display surface and a plurality of cavities in the display surface; and
a plurality of pixel units, each pixel unit of the plurality of pixel units including a first light emitter and a second light emitter located in a corresponding cavity of the plurality of cavities, the first light emitter and the second light emitter being arranged in a same pattern in each cavity of the plurality of cavities, the each pixel unit of the plurality of pixel units including a redundant structure configured to cause one of the first light emitter and the second light emitter to be driven to emit light,
wherein each of the first light emitter and the second light emitter includes a first terminal and a second terminal spaced from each other as viewed in a plan view, and includes an emission portion located adjacent to the first terminal or to the second terminal in a corresponding one of the first light emitter and the second light emitter, and
each of the plurality of cavities includes, on a bottom surface of the cavity, a first electrode connected to the first terminal and a second electrode connected to the second terminal, and the first electrode or the second electrode corresponding to the first terminal or the second terminal located adjacent to the emission portion is in a central portion of the bottom surface.

10. The display device according to claim 9, wherein
the first terminal is an anode terminal, the second terminal is a cathode terminal, the first electrode is an anode electrode, the second electrode is a cathode electrode, and the second electrode is in the central portion of the bottom surface.

11. The display device according to claim 9, wherein
the first light emitter and the second light emitter are different in that they are driven according to the each pixel unit.

12. The display device according to claim 11, further comprising:
a drive controller configured to perform first driving to drive the first light emitter or second driving to drive the second light emitter for the each pixel unit of the plurality of pixel units,
wherein the drive controller performs the first driving for a predetermined proportion of the plurality of pixel units, and performs the second driving for the remaining pixel units among the plurality of pixel units.

13. The display device according to claim 11, further comprising:
a drive controller configured to perform first driving to drive the first light emitter or second driving to drive the second light emitter for each of the plurality of pixel units,
wherein the drive controller changes, for every one or more frames, pixel units of the plurality of pixel units for the first driving and pixel units of the plurality of pixel units for the second driving.

14. The display device according to claim 11, wherein
the plurality of pixel units is arranged in a matrix, and
the one of the first light emitter and the second light emitter emits light in each of pixel units of the plurality of pixel units in one of two adjacent rows of the matrix, and another of the first light emitter and the second light emitter emits light in each of pixel units of the plurality of pixel units in another of the two adjacent rows.

15. The display device according to claim 11, wherein
the plurality of pixel units is arranged in a matrix, and
the one of the first light emitter and the second light emitter emits light in each of pixel units of the plurality of pixel units in one of two adjacent columns of the matrix, and another of the first light emitter and the second light emitter emits light in each of pixel units of the plurality of pixel units in another of the two adjacent columns.

16. The display device according to claim 11, wherein
the plurality of pixel units is arranged in a matrix, and
the one of the first light emitter and the second light emitter emits light in a pixel unit of the plurality of pixel units, and another of the first light emitter and the second light emitter emits light in each of two pixel units of the plurality of pixel units adjacent to the pixel unit in a row direction of the matrix and in each of two pixel units of the plurality of pixel units adjacent to the pixel unit in a column direction of the matrix.

17. The display device according to claim 11, wherein
the first light emitter and the second light emitter included in a pixel unit of the plurality of pixel units have an emission characteristic different from an emission characteristic of the first light emitter and the second light emitter included in another pixel unit of the plurality of pixel units.

18. The display device according to claim 1, wherein
each of the first light emitter and the second light emitter includes a micro-light-emitting diode.

19. The display device according to claim 9, wherein
each of the first light emitter and the second light emitter includes a micro-light-emitting diode.
